(19) United States
(12) Patent Application Publication
(10) Pub. No.: US 2024/0030131 A1
(43) Pub. Date: Jan. 25, 2024

(54) SEMICONDUCTOR DEVICE

(71) Applicant: RENESAS ELECTRONICS CORPORATION, Tokyo (JP)

(72) Inventors: Eisuke KODAMA, Tokyo (JP); Tohru KAWAI, Tokyo (JP)

(21) Appl. No.: 18/333,033

(22) Filed: Jun. 12, 2023

(30) Foreign Application Priority Data
Jul. 25, 2022 (JP) 2022-117867

(51) Int. Cl. H01L 23/525; H01L 23/532

(52) U.S. Cl. CPC H01L 23/5256; H01L 23/53271; H01L 23/53209

(57) ABSTRACT

An electric fuse including a fuse body and a fuse pad has a lamination structure of a polysilicon film and a cobalt silicide film. In the fuse body, a first portion having a first thickness and a second portion having a second thickness are formed. The first thickness is smaller than the second thickness. The polysilicon film is formed such that a thickness of the polysilicon film in the first portion becomes smaller than a thickness of the polysilicon film in the second portion.

### CROSS-REFERENCE TO RELATED APPLICATIONS

The disclosure of Japanese Patent Application No. 2022-117867 filed on Jul. 25, 2022, including the specification, drawings and abstract is incorporated herein by reference in its entirety.

### BACKGROUND

The present disclosure relates to a semiconductor device, and can be suitably used, for example, for a semiconductor device including an electric fuse.

There are disclosed techniques listed below.
[Patent Document 1] Japanese Unexamined Patent Application Publication No. 2009-295673
[Patent Document 2] Japanese Unexamined Patent Application Publication No. 2011-222691

There is a semiconductor device including an electric fuse to remedy a defect circuit after it has been molded (Patent Document 1 and Patent Document 2). The electric fuse is cut by applying a current to the electric fuse.

The electric fuse has a two-layer structure of a polysilicon film and a metal silicide film. The metal silicide film is formed on the polysilicon film. The current mainly flows through the metal silicide film, so that the temperature of the metal silicide film increases to the melting point. When the heat of the metal silicide film is conducted to the polysilicon film, the temperature of the polysilicon film increases, the polysilicon film is melted, and the electric fuse is cut.

Conventionally, a tungsten silicide film (WSi) or a titanium silicide film (TiSi) has been applied as a metal silicide film, but a cobalt silicide film (CoSi) which is advantageous in terms of processing is applied in accordance with miniaturization of semiconductor device and the like.

### SUMMARY

In an electric fuse to which a tungsten silicide film is applied, the melting point of tungsten (W) is about 3422° C. with respect to the melting point (1414° C.) of silicon (Si). In an electric fuse to which a titanium silicide film is applied, the melting point of titanium (Ti) is about 1668° C. with respect to the melting point (1414° C.) of silicon (Si). On the other hand, in an electric fuse to which a cobalt silicide film is applied, the melting point of cobalt (Co) is about 1495° C. with respect to the melting point (1414° C.) of silicon (Si). Therefore, the temperature difference between the melting point of cobalt and the melting point of silicon is sufficiently smaller than the temperature difference between the melting point of tungsten and the melting point of silicon and the temperature difference between the melting point of titanium and the melting point of silicon.

As described above, since the temperature difference between the melting point of cobalt and the melting point of silicon is small, it is assumed that the heat of the cobalt silicide film is not sufficiently conducted to silicon when the temperature of the cobalt silicide film increases to the melting point due to the current mainly flowing through the cobalt silicide film, and that the temperature of silicon does not increase to the melting point. As a result, there is a possibility that the electric fuse cannot be melted.

Other objects and novel features will become apparent from the description of this specification and the accompanying drawings.

A semiconductor device according to one embodiment includes a semiconductor substrate and an electric fuse. The semiconductor substrate has a main surface. The electric fuse includes a fuse body formed on the main surface, having a width, and extending in one direction. The fuse body includes a first layer and a second layer. The first layer has a first melting point. The second layer is laminated in contact with the first layer and has a second melting point higher than the first melting point. The fuse body includes a first portion having a first thickness and a second portion having a second thickness. The first portion is to be cut as the electric fuse. The second portion is connected to the first portion. The first thickness of the first portion is smaller than the second thickness of the second portion. A thickness of the first layer in the first portion of the fuse body is smaller than a thickness of the first layer in the second portion.

A semiconductor device according to another embodiment includes a semiconductor substrate and an electric fuse. The semiconductor substrate has a main surface. The electric fuse includes a fuse body formed on the main surface, having a width, and extending in one direction. The fuse body includes a first layer and a second layer. The first layer has a first melting point. The second layer is laminated in contact with the first layer and has a second melting point higher than the first melting point. The fuse body includes a first portion having a first thickness and a second portion having a second thickness. The first portion is to be cut as the electric fuse. The second portion is connected to the first portion. The first thickness of the first portion is larger than the second thickness of the second portion. A thickness of the second layer in the first portion of the fuse body is larger than a thickness of the second layer in the second portion.

A semiconductor device according to still another embodiment includes a semiconductor substrate, an electric fuse, and a heat sink. The semiconductor substrate has a main surface. The electric fuse includes a fuse body formed on the main surface, having a width, and extending in a first direction. The heat sink is disposed over the fuse body via a dielectric material. The fuse body includes a first layer and a second layer. The first layer has a first melting point. The second layer is laminated in contact with the first layer between the first layer and the heat sink, and has a second melting point higher than the first melting point.

According to the semiconductor device of one embodiment, it is possible to improve the melting property of the electric fuse.

According to the semiconductor device of another embodiment, it is possible to improve the melting property of the electric fuse.

According to the semiconductor device of still another embodiment, it is possible to improve the melting property of the electric fuse.

### BRIEF DESCRIPTION OF THE DRAWINGS

FIG. 1 is a circuit diagram of an electric fuse in a semiconductor device according to each embodiment.

FIG. 2 is a plan view showing an exemplary planar configuration of an electric fuse in a semiconductor device according to a first embodiment.

FIG. 3 is a cross-sectional view along the cross-sectional line III-III shown in FIG. 1 in the first embodiment.

FIG. 4 is a cross-sectional view along the cross-sectional line IV-IV shown in FIG. 1 in the first embodiment.

FIG. 5 is a diagram showing a relationship between an application time of a current to the electric fuse and a temperature of the electric fuse and a relationship between the application time of the current and a current flowing through the electric fuse, according to a comparative example.

FIG. 6 is a diagram showing a relationship between an application time of a current to the electric fuse and a temperature of the electric fuse and a relationship between the application time of the current and a current flowing through the electric fuse, in the first embodiment.

FIG. 7 is a diagram showing the actions and the effects of the electric fuse in the first embodiment together with the comparative example.

FIG. 8 is a cross-sectional view showing an exemplary configuration of an electric fuse in a semiconductor device according to a modified example in the first embodiment.

FIG. 9 is a plan view showing an exemplary planar configuration of an electric fuse in a semiconductor device according to a second embodiment.

FIG. 10 is a cross-sectional view along the cross-sectional line X-X shown in FIG. 9 in the second embodiment.

FIG. 11 is a cross-sectional view along the cross-sectional line XI-XI shown in FIG. 9 in the second embodiment.

FIG. 12 is a diagram showing the actions and the effects of the electric fuse in the second embodiment together with the comparative example.

FIG. 13 is a plan view showing an exemplary planar configuration of an electric fuse in a semiconductor device according to a first example of a third embodiment.

FIG. 14 is a cross-sectional view along the cross-sectional line XIV-XIV shown in FIG. 13 in the third embodiment.

FIG. 15 is a cross-sectional view along the cross-sectional line XV-XV shown in FIG. 13 in the third embodiment.

FIG. 16 is a plan view showing an exemplary planar configuration of an electric fuse in a semiconductor device according to a second example of the third embodiment.

FIG. 17 is a cross-sectional view along the cross-sectional line XVII-XVII shown in FIG. 16 in the third embodiment.

FIG. 18 is a cross-sectional view along the cross-sectional line XVIII-XVIII shown in FIG. 16 in the third embodiment.

FIG. 19 is a plan view showing an exemplary planar configuration of an electric fuse in a semiconductor device according to a third example of the third embodiment.

FIG. 20 is a cross-sectional view along the cross-sectional line XX-XX shown in FIG. 19 in the third embodiment.

FIG. 21 is a cross-sectional view along the cross-sectional line XXI-XXI shown in FIG. 19 in the third embodiment.

### DETAILED DESCRIPTION

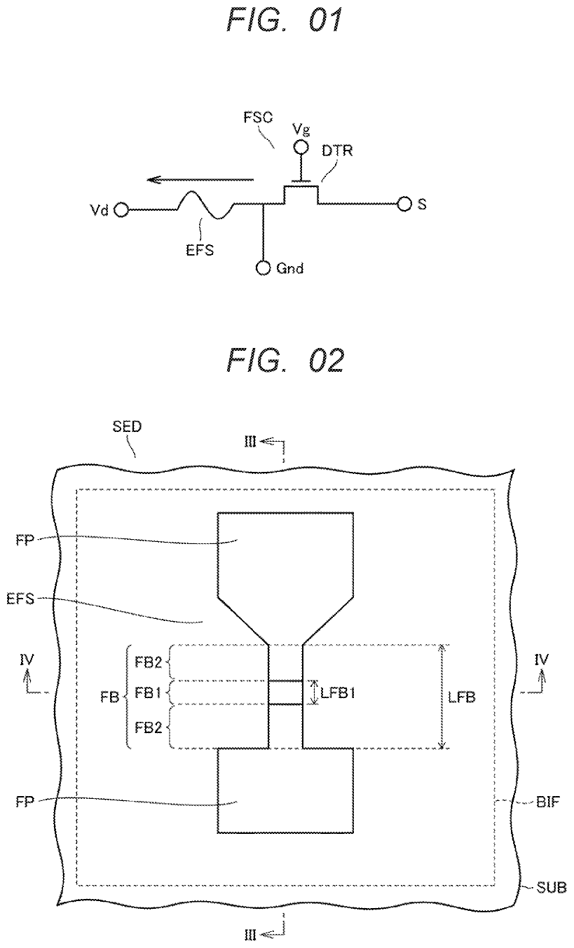

First, an exemplary fuse circuit including an electric fuse in the semiconductor device according to each embodiment will be described. As shown in FIG. 1, an electric fuse EFS and a driver transistor DTR are electrically connected to an electric fuse circuit FSC. By turning on the driver transistor DTR, current flows through the electric fuse EFS (refer to arrows). Hereinafter, the structure of the electric fuse EFS according to each embodiment will be described in detail.

### First Embodiment

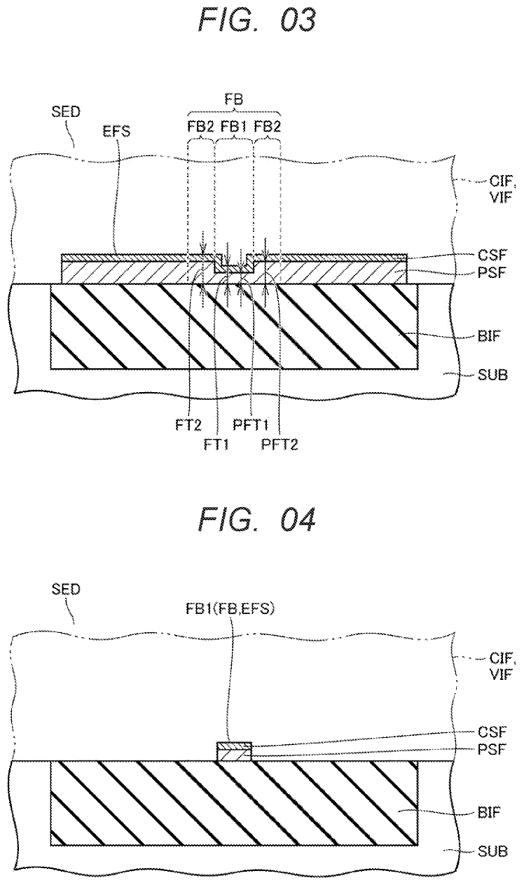

An exemplary electric fuse according to the first embodiment will be described. As shown in FIGS. 2, 3, and 4, the electric fuse EFS includes a fuse body FB and a fuse pad FP. The fuse body FB (electric fuse EFS) has a lamination structure of a polysilicon film PSF (first layer) and a cobalt silicide film CSF (second layer), and the cobalt silicide film CSF is formed so as to be in contact with the polysilicon film PSF. The melting point of the cobalt silicide film CSF is higher than the melting point of the polysilicon film PSF.

In the fuse body FB, a first portion FB1 having a thickness FT1 (first thickness) and a second portion FB2 having a thickness FT2 (second thickness) are formed. The thickness FT1 is smaller than the thickness FT2. Each of the thickness FT1 and the thickness FT2 corresponds to a height from the lower surface of the polysilicon film PSF to the upper surface of the cobalt silicide film CSF. That is, each of the thickness FT1 and the thickness FT2 is a total thickness of the thickness of the polysilicon film PSF and the thickness of the cobalt silicide film CSF.

In the electric fuse EFS, the polysilicon film PSF is formed such that a thickness PFT1 of the polysilicon film PSF in the first portion FB1 becomes smaller than a thickness PFT2 of the polysilicon film PSF in the second portion FB2. The thickness PFT1 of the polysilicon film PSF is set to about 5% to 90% of the thickness PFT2 of the polysilicon film PSF. In addition, it is preferable that the first portion FB1 is formed such that, in a manner including the center portion of the fuse body FB in a longitudinal direction, a length LFB1 of the first portion FB has a length of at least 5% of a length LFB of the fuse body FB.

The electric fuse EFS is formed in the same step as the step of forming the gate electrode of the driver transistor DTR (refer to FIG. 1), for example. After a polysilicon film (not shown) is formed so as to cover a main surface of a semiconductor substrate SUB, an etching process is performed to the portion of the polysilicon film located in the region to be the first portion FB1. As a result, the thickness of the polysilicon film located in the region to be the first portion FB1 becomes smaller than the thickness of the polysilicon film located in the region to be the second portion FB2.

Next, after the polysilicon film is patterned into the electric fuse EFS shape, a cobalt film (not shown) is formed so as to cover the polysilicon film. Next, the cobalt silicide film is formed in a self-aligned manner by reacting cobalt with silicon, and the unreacted cobalt film is removed, whereby the electric fuse EFS is formed.

When the thickness PFT1 of the polysilicon film PSF is smaller than 5% of the thickness PFT2 of the polysilicon film PSF, it is difficult to control the etching process of the polysilicon film. On the other hand, when the thickness PFT1 of the polysilicon film PSF is larger than 90% of the thickness PFT2 of the polysilicon film PSF, the polysilicon film PSF is difficult to melt.

In a semiconductor device SED described above, since the thickness FT1 of the first portion FB1 in the fuse body FB of the electric fuse EFS is smaller than the thickness FT2 of the second portion FB2, the fuse body FB can be more reliably melted. This will be explained.

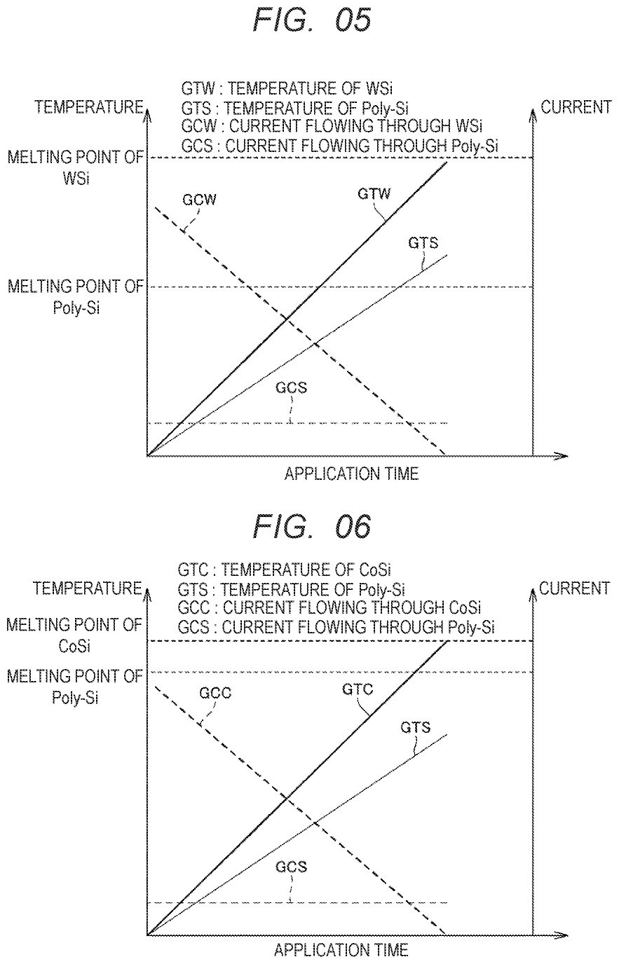

First, an electric fuse in which a tungsten silicide film (WSi) is applied as a metal silicide film will be described. FIG. 5 shows a graph GTW of the temperature change of the tungsten silicide film and a graph GTS of the temperature change of the polysilicon film, respectively, with respect to the period of time from the start of the current flowing through the electric fuse. Also, a graph GCW of the change in the current flowing through the tungsten silicide film and a graph GCS of the change in the current flowing through the polysilicon film with respect to the period of time from the start of the current flowing through the electric fuse are respectively shown.

When a current begins to flow through the electric fuse, the current mainly flows through the tungsten silicide film. As shown in FIG. 5, a current flows through the tungsten silicide film, so that electromigration occurs and the temperature of the tungsten silicide film increases. As the electromigration progresses, the current flowing through the tungsten silicide film gradually decreases. When the temperature of the tungsten silicide film reaches the melting point, the tungsten silicide film is cut (melted) by electromigration, and no current flows through the tungsten silicide film.

Here, the melting point of the tungsten silicide film (melting point of tungsten: 3422° C.) is sufficiently higher than the melting point of the polysilicon film (melting point of silicon: 1414° C.). Therefore, when the temperature of the tungsten silicide film reaches the melting point, the heat of the tungsten silicide film is sufficiently supplied to the polysilicon film, and the temperature of the polysilicon film also reaches the melting point. When the temperature of the polysilicon film reaches the melting point, the polysilicon film melts and the polysilicon film volatilizes. When volatilizing, the pressure increases, and a void is formed in the electric fuse, and the electric fuse is cut (melted). Note that a substantially constant current flows through the polysilicon film until the electric fuse is cut.

Next, an electric fuse in which a cobalt silicide film (CoSi) is applied as the metal silicide film will be described. FIG. 6 shows a graph GTC of the temperature change of the cobalt silicide film and the graph GTS of the temperature change of the polysilicon film, respectively, with respect to the period of time from the start of the current flowing through the electric fuse. Also, a graph GCC of the change in the current flowing through the cobalt silicide film and the graph GCS of the change in the current flowing through the polysilicon film with respect to the period of time from the start of the current flowing through the electric fuse are respectively shown.

When a current begins to flow through the electric fuse, the current mainly flows through the cobalt silicide film. As shown in FIG. 6, when a current flows through the cobalt silicide film, electromigration occurs, and the temperature of the cobalt silicide film increases. As the electromigration progresses, the current flowing through the cobalt silicide film gradually decreases. When the temperature of the cobalt silicide film reaches the melting point, the cobalt silicide film is cut (melted) by electromigration, and no current flows through the cobalt silicide film.

Here, the melting point of the cobalt silicide film (melting point of cobalt: 1495° C.) is close to the melting point of the polysilicon film (melting point of silicon: 1414° C.) That is, the temperature difference between the melting point of the cobalt silicide film and the melting point of the polysilicon film is smaller than the temperature difference between the melting point of the tungsten silicide film and the melting point of the polysilicon film. Therefore, when the temperature of the cobalt silicide film reaches the melting point, the heat of the cobalt silicide film is not sufficiently supplied to the polysilicon film, and the temperature of the polysilicon film does not reach the melting point.

When the temperature of the cobalt silicide film reaches the melting point, the cobalt silicide film is cut (melted) by electromigration, so that no current flows through the cobalt silicide film, and heat cannot be supplied to the polysilicon film. As a result, in the electric fuse to which the cobalt silicide film is applied, there is a possibility that cutting (melting) of the electric fuse cannot be reliably performed.

In the present first embodiment, in the electric fuse EFS to which the cobalt silicide film CSF is applied, the fuse body FB has a configuration in which the thickness FT1 of the first portion FB1 is smaller than the thickness FT2 of the second portion FB2. In particular, the thickness PFT1 of the polysilicon film PSF in the first portion FB1 is smaller than the thickness PFT2 of the polysilicon film PSF in the second portion FB2.

Here, a temperature distribution generated in the polysilicon film PSF by supplying heat from the cobalt silicide film CSF to the polysilicon film PSF will be described.

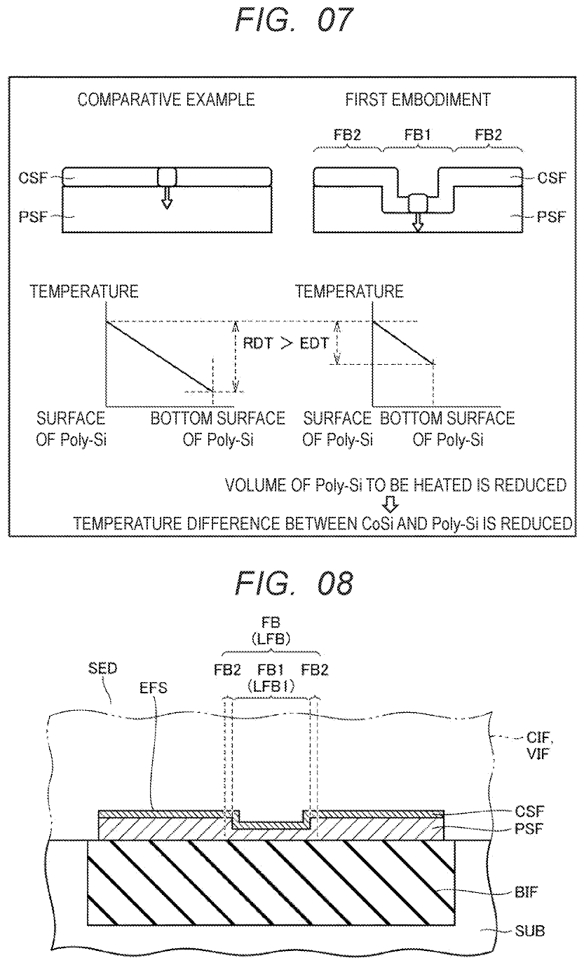

FIG. 7 shows the temperature distribution of the polysilicon film PSF in the first portion FB1 from the upper surface of the polysilicon film PSF that contacts the cobalt silicide film CSF to the lower surface of the polysilicon film PSF (on the right side). Further, as the comparative example, the temperature distribution of the polysilicon film (on the left side) when the film thickness of the polysilicon film PSF is constant (only in the thickness FT2), is also shown.

As shown in FIG. 7, the temperature of the polysilicon film PSF tends to gradually decrease from the upper surface toward the lower surface. In the electric fuse EFS according to the first embodiment, since the thickness of the polysilicon film PSF is small, a temperature difference EDT between the temperature at the upper surface and the temperature at the lower surface is smaller than a corresponding temperature difference RDT in the comparative example. In other words, in the electric fuse EFS according to the first embodiment, the volume of the polysilicon film PSF to which heat is supplied from the cobalt silicide film CSF is smaller than the corresponding volume in the comparative example.

As a result, the slope of the temperature change of the polysilicon film with respect to the period of time after the current begins to flow is larger than the slope in the comparative example. Therefore, when the temperature of the cobalt silicide film CSF reaches the melting point, the heat of the cobalt silicide film CSF is sufficiently supplied to the polysilicon film PSF, so that the temperature of the polysilicon film PSF can reach the melting point. Consequently, the electric fuse EFS to which the cobalt silicide film CSF is applied can be cut (melted) more reliably.

### Modified Example

As shown in FIG. 8, in the electric fuse EFS of the semiconductor device SED according to the modified example, in particular, the length LFB1 of the first portion FB1 may be set to a length equal to or greater than half (50%) of the length LFB of the fuse body FB.

In the above-described electric fuse EFS, since the electric resistance of the electric fuse EFS increases as the length LFB1 of the first portion FB1 having a small thickness increases, the current flowing through the electric fuse EFS via the driver transistor needs to be increased. In order to increase the current, the size of the driver transistor needs to be increased. In order to reduce the size of semiconductor device, the length of the first portion FB1 needs to be set so that the driver transistor does not need to be formed to be large.

### Second Embodiment

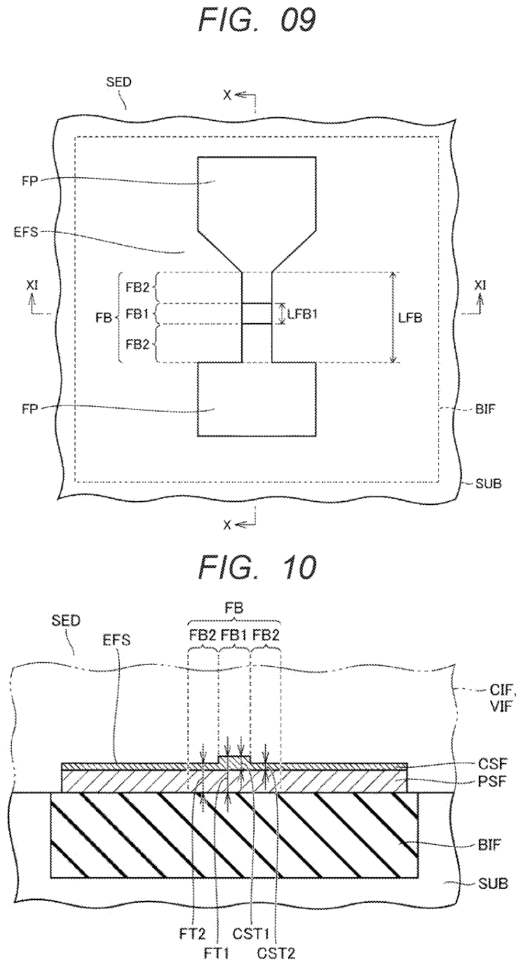

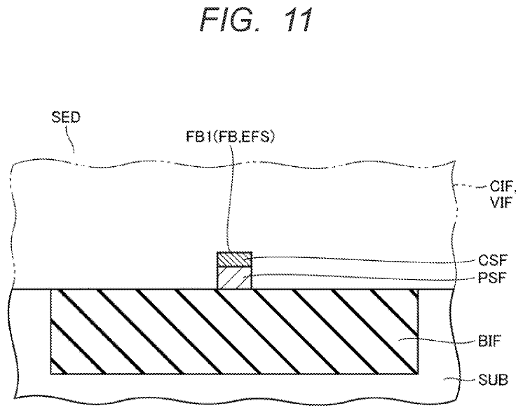

An exemplary electric fuse according to the second embodiment will be described. As shown in FIGS. 9, 10, and 11, the electric fuse EFS includes the fuse body FB and the fuse pad FP. In the fuse body FB, the first portion FB1 having the thickness FT1 (first thickness) and the second portion FB2 having the thickness FT2 (second thickness) are formed. The thickness FT1 is larger than the thickness FT2.

In the electric fuse EFS, the cobalt silicide film CSF is formed such that a thickness CST1 of the cobalt silicide film CSF in the first portion FB1 is larger than a thickness CST2 of the cobalt silicide film CSF in the second portion FB2. The thickness CST1 of the cobalt silicide film CSF is about 1% to 20% larger than the thickness CST2 of the cobalt silicide film CSF.

In addition, it is preferable that the first portion FB1 is formed such that, in a manner including the center portion of the fuse body FB in the longitudinal direction, the length LFB1 of the first portion FB1 has a length of about 5% to 50% of the length LFB of the fuse body FB. Note that substantially the same members as those of the electric fuse EFS shown in FIG. 2 and the like are denoted by the same reference numerals, and the explanation thereof will not be repeated unless otherwise required.

The electric fuse EFS is formed in the same step as the step of forming the gate electrode of the driver transistor DTR (refer to FIG. 1), for example. After a polysilicon film (not shown) is formed so as to cover the main surface of the semiconductor substrate SUB, n-type impurities are implanted into a part of the polysilicon film located in the region to be the first portion FB1. Next, after the polysilicon film is patterned into the electric fuse EFS shape, a cobalt film (not shown) is formed so as to cover the polysilicon film.

Next, a cobalt silicide film is formed in a self-aligned manner by reacting cobalt with silicon. In this case, in the cobalt film covering the portion of the polysilicon film into which the n-type impurities are implanted, the cobalt silicide film is formed to be thicker than the cobalt film covering the portion of the polysilicon film into which the n-type impurities are not implanted. Thereafter, the electric fuse EFS is formed by removing the unreacted cobalt film.

In the semiconductor device SED described above, since the thickness CST1 of the cobalt silicide film CSF in the fuse body FB of the electric fuse EFS is larger than the thickness CST2 of the cobalt silicide film CSF in the second portion FB2, the fuse body FB can be more reliably melted. This will be explained.

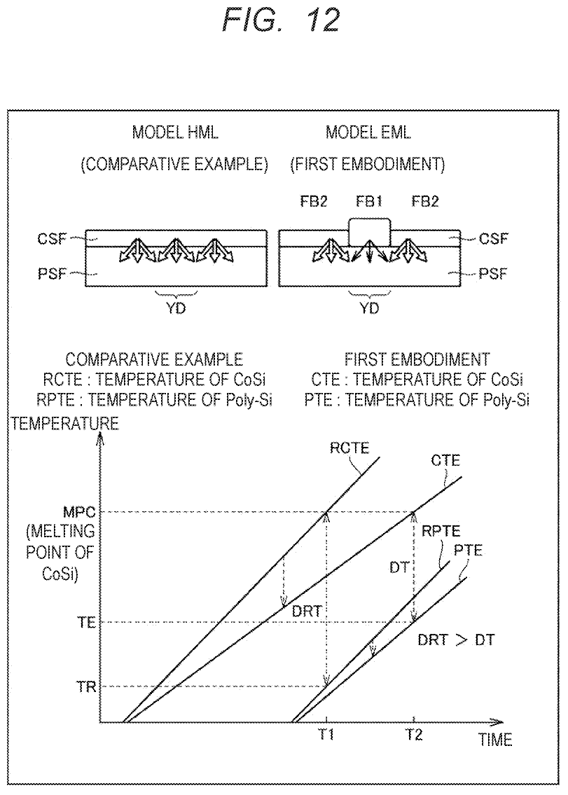

FIG. 12 shows a model EML schematically showing a state in which heat generated from the cobalt silicide film CSF by a current flowing through the electric fuse EFS according to the second embodiment is conducted to the polysilicon film PSF. Further, a model HML schematically showing a state in which heat generated from the cobalt silicide film CSF by a current flowing through the electric fuse EFS according to the comparative example is conducted to the polysilicon film PSF, is shown. Incidentally, the width of the arrow is a schematic representation of the magnitude of the heat emitted.

Further, the relationship between the application time of the current and the temperature of the fuse body of the electric fuse according to the second embodiment is shown in a graph CTE and a graph PTE. In addition, the relationship between the application time of the current and the temperature of the fuse body of the electric fuse according to the comparative example is shown in a graph RCTE and a graph RPTE. The graph CTE shows the temperature change of the cobalt silicide film with respect to the period of time from the start of the current flowing through the electric fuse. The graph PTE shows the temperature change of the polysilicon film with respect to the period of time after the start of the current flowing through the electric fuse.

First, the electric fuse EFS according to the comparative example will be described. In the electric fuse EFS according to the comparative example, as shown in the model HML, the fuse body FB has a uniform thickness along the extending direction. Therefore, when conducting through the polysilicon film PSF, heat generated by the current flowing mainly through the cobalt silicide film CSF is conducted to the polysilicon film PSF substantially uniformly along the extension direction.

In this case, as shown in the graph RCTE, the temperature of the cobalt silicide film CSF increases with the passage of time from the start of the current flow. As the heat generated in the cobalt silicide film CSF is conducted to the polysilicon film PSF, the temperature of the polysilicon film PSF also starts to increase as shown in the graph RPTE. Here, the time when the temperature of the cobalt silicide film CSF of the electric fuse EFS of the reference reaches a melting point MPC is referred to as a time T1, and the temperature of the polysilicon film PSF at the time T1 is referred to as a temperature TR. Here, the temperature difference DRT between the temperature (melting point) of the cobalt silicide film CSF and the temperature TR of the polysilicon film PSF is “the melting point MPC minus temperature TR”.

Next, the electric fuse EFS according to the second embodiment will be described. In the electric fuse EFS according to the second embodiment, as shown in the model EML, in the fuse body FB, the thickness CST1 of the cobalt silicide film CSF in the first portion FB1 is larger than the thickness CST2 of the cobalt silicide film CSF in the second portion FB2. That is, the volume of the cobalt silicide film CSF located in the first portion FB1 is larger than the volume of the cobalt silicide film CSF located in the first portion FB1 in the comparative example.

Therefore, as shown in the graph CTE, in the cobalt silicide film CSF according to the second embodiment, the temperature increasing rate of the cobalt silicide film CSF becomes slower with the passage of time from the start of the current flow by the increasing volume, and the time (time T2) until the melting point is reached becomes longer than the time (time T1) in the comparative example.

On the other hand, in the polysilicon film PSF, although the amount of heat generated from the cobalt silicide film CSF located in the first portion FB1 to be supplied to the polysilicon film PSF located immediately below is slightly reduced, there is no change of the amount of heat generated from the cobalt silicide film CSF in the second portion FB2 located in the vicinity of the first portion FB1 to be supplied to the polysilicon film PSF located in the first portion FB1.

Therefore, as shown in the graph PTE, in the polysilicon film PSF according to the second embodiment, although the temperature increasing rate of the polysilicon film PSF slightly slows with the passage of time from the start of the current flow, the temperature of the polysilicon film PSF increases during that time as the time until the temperature of the cobalt silicide film CSF reaches the melting point increases.

Thus, the temperature TE of the polysilicon film PSF at the time when the temperature of the cobalt silicide film CSF reaches the melting point becomes higher than the temperature TR of the polysilicon film PSF in the comparative example. Consequently, the temperature difference DT (melting point MPC minus temperature TE) between a temperature (melting point) of the cobalt silicide film CSF and the temperature TE of the polysilicon film PSF becomes smaller than the temperature difference DRT in the comparative example, and the polysilicon film PSF easily melts.

As described above, the temperature of the polysilicon film PSF can be increased by securing a longer period of time until the temperature of the cobalt silicide film CSF reaches the melting point. As a result, the temperature difference between the temperature (melting point) of the cobalt silicide film CSF and the temperature of the polysilicon film PSF is reduced, and the polysilicon film PSF is easily melted. Consequently, the electric fuse EFS can be cut more reliably.

### Third Embodiment

### First Example

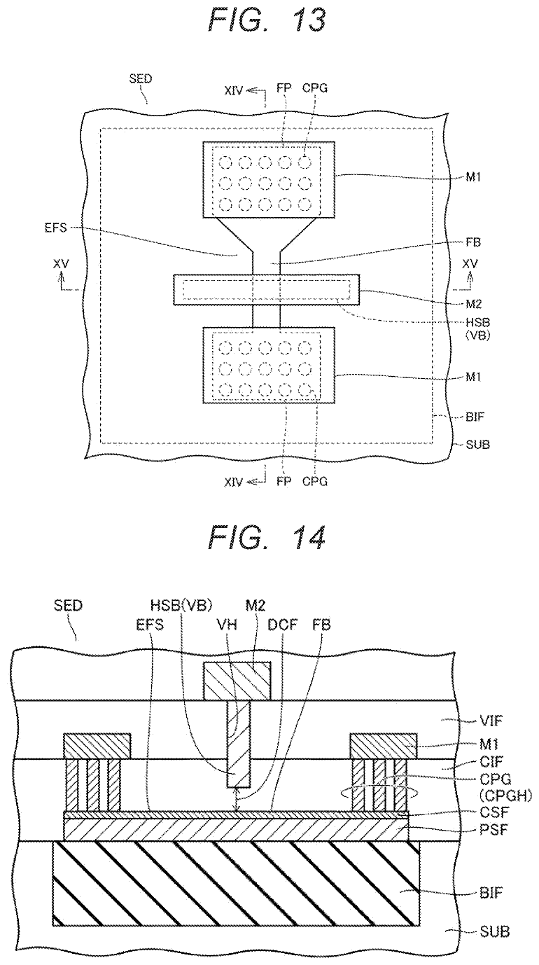

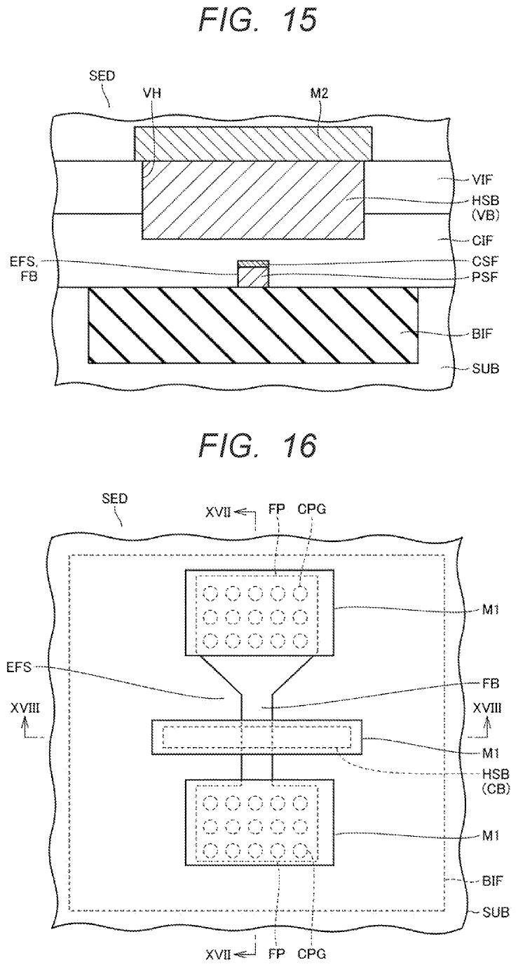

A first example of an electric fuse according to the third embodiment will be described. As shown in FIGS. 13, 14, and the electric fuse EFS is disposed on an isolation dielectric film BIF formed in the semiconductor substrate SUB. The electric fuse EFS includes the fuse body FB and the fuse pad FP.

A contact interlayer dielectric film CIF is formed to cover the electric fuse EFS. A contact plug CPG is formed in a contact hole CPGH penetrating the contact interlayer dielectric film CIF. A first wiring layer M1 is formed on the contact interlayer dielectric film CIF. A via interlayer dielectric film VIF is formed to cover the first wiring layer M1. A second wiring layer M2 is formed on the via interlayer dielectric film VIF. An interlayer dielectric film or the like is further formed so as to cover the second wiring layer M2.

A heat sink HSB that absorbs the heat of the fuse body FB is formed as a via wiring VB from a position of the upper surface of the via interlayer dielectric film VIF corresponding to the lower surface of the second wiring layer M2 to a position closer to the semiconductor substrate SUB than the interface between the via interlayer dielectric film VIF and the contact interlayer dielectric film CIF. The heat sink HSB is formed so as to extend in a direction intersecting with a direction in which the fuse body FB extends. The contact interlayer dielectric film CIF corresponding to a thickness DCF is interposed between the fuse body FB and the heat sink HSB. The thickness DCF is, for example, about 0.05 μm to 2 μm. Note that substantially the same members as those of the electric fuse EFS shown in FIG. 2 and the like are denoted by the same reference numerals, and the explanation thereof will not be repeated unless otherwise required.

The above-described electric fuse EFS is formed in the same step as the step of forming the gate electrode of the driver transistor DTR (refer to FIG. 1), for example. After the electric fuse EFS is formed, for example, the contact interlayer dielectric film CIF such as a silicon oxide film is formed so as to cover the electric fuse EFS. Next, the contact hole CPGH is formed in the contact interlayer dielectric film CIF. The contact plug CPG is formed in the contact hole CPGH. Next, the first wiring layer M1 is formed on the contact interlayer dielectric film CIF. The first wiring layer M1 is electrically connected to the fuse pad FP in the electric fuse EFS via the contact plug CPG.

Next, the via interlayer dielectric film VIF such as a silicon oxide film is formed so as to cover the first wiring layer M1 or the like. Next, an opening portion VH is formed in the via interlayer dielectric film VIF. At this time, the first wiring is not formed directly above the fuse body FB. Therefore, the opening portion VH is formed so as to penetrate through the via interlayer dielectric film VIF and reach the contact interlayer dielectric film CIF by overetching when forming the opening portion VH.

Here, the opening portion VH is formed so as to reach a depth at which the predetermined distance DCF between the heat sink HSB and the fuse body FB is secured. Next, the heat sink HSB is formed in the opening portion VH. Next, the second wiring layer M2 is formed on the via interlayer dielectric film VIF. Next, an interlayer dielectric film or the like is further formed so as to cover the second wiring layer M2.

In the above-described electric fuse EFS, the heat sink HSB is disposed directly above a portion to be fused in the fuse body FB. The heat sink HSB mainly has a function of absorbing heat generated by a current flowing through the cobalt silicide film CSF. Therefore, the heat of the portion to be melted in the fuse body FB is absorbed by the heat sink HSB, the temperature increasing time of the cobalt silicide film CSF located in the portion to be melted becomes slower than when the heat sink HSB is not disposed with the passage of time from the start of the current flow, and the time until the melting point is reached becomes longer.

Since the time until the temperature of the cobalt silicide film CSF reaches the melting point is longer than the time when the heat sink HSB is not disposed, the temperature of the polysilicon film PSF can be increased in the meantime. As a result, the temperature difference between the temperature (melting point) of the cobalt silicide film CSF and the temperature of the polysilicon film PSF is reduced, and the polysilicon film PSF is easily melted. Consequently, the electric fuse EFS can be cut more reliably.

### Second Example

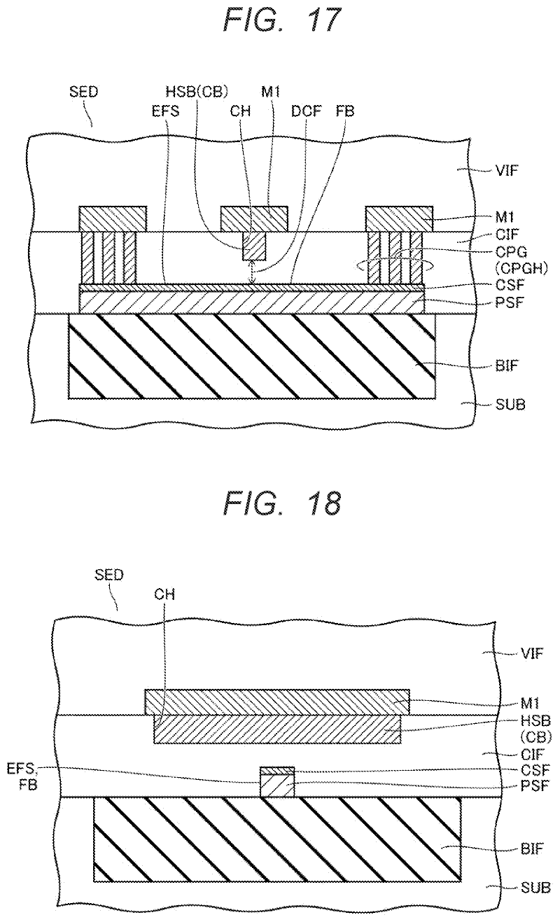

A second example of an electric fuse according to the third embodiment will be described. As shown in FIGS. 16, 17, and 18, the electric fuse EFS is disposed on the isolation dielectric film BIF formed in the semiconductor substrate SUB. The contact interlayer dielectric film CIF is formed to cover the electric fuse EFS. The contact plug CPG is formed in the contact hole CPGH penetrating the contact interlayer dielectric film CIF. The first wiring layer M1 is formed on the contact interlayer dielectric film CIF. The via interlayer dielectric film VIF or the like is formed so as to cover the first wiring layer M1.

The heat sink HSB that absorbs heat of the fuse body FB is formed as a contact portion CB from a position of the upper surface of the contact interlayer dielectric film CIF corresponding to the lower surface of the first wiring layer M1 to a position closer to the semiconductor substrate than the lower surface of the first wiring layer M1. The heat sink HSB is formed so as to extend in a direction intersecting with a direction in which the fuse body FB extends. The contact interlayer dielectric film CIF corresponding to the thickness DCF is interposed between the fuse body FB and the heat sink HSB. The thickness DCF is, for example, about 0.05 μm to 2 μm. Note that substantially the same members as those of the electric fuse EFS shown in FIG. 2 and the like are denoted by the same reference numerals, and the explanation thereof will not be repeated unless otherwise required.

The above-described electric fuse EFS is formed in the same step as the step of forming the gate electrode of the driver transistor DTR (refer to FIG. 1), for example. After the electric fuse EFS is formed, the contact interlayer dielectric film CIF such as a silicon oxide film is formed so as to cover the electric fuse EFS. Next, the contact hole CPGH and an opening portion CH are sequentially formed in the contact interlayer dielectric film CIF. Here, the opening portion CH is formed so as to reach a depth at which the predetermined distance DCF between the heat sink HSB and the fuse body FB is secured.

Next, the contact plug CPG is formed in the contact hole CPGH. In addition, the heat sink HSB is formed in the opening portion CH. Next, the first wiring layer M1 is formed on the contact interlayer dielectric film CIF. The first wiring layer M1 is electrically connected to the fuse pad FP in the electric fuse EFS via the contact plug CPG. Next, the via interlayer dielectric film VIF or the like is further formed so as to cover the first wiring layer M1.

In the above-described electric fuse EFS, the heat sink HSB is disposed directly above a portion to be melted in the fuse body FB. The heat sink HSB mainly has a function of absorbing heat generated by a current flowing through the cobalt silicide film CSF. Therefore, the heat of the portion to be melted in the fuse body FB is absorbed by the heat sink HSB, the temperature increasing rate of the cobalt silicide film CSF located in the portion to be melted becomes slower than when the heat sink HSB is not disposed with the passage of time from the start of the current flow, and the time until the melting point is reached becomes longer.

Since the time until the temperature of the cobalt silicide film CSF reaches the melting point is longer than the time when the heat sink HSB is not disposed, the temperature of the polysilicon film PSF can be increased in the meantime. As a result, the temperature difference between the temperature (melting point) of the cobalt silicide film CSF and the temperature of the polysilicon film PSF is reduced, and the polysilicon film PSF is easily melted. Consequently, the electric fuse EFS can be cut more reliably.

### Third Example

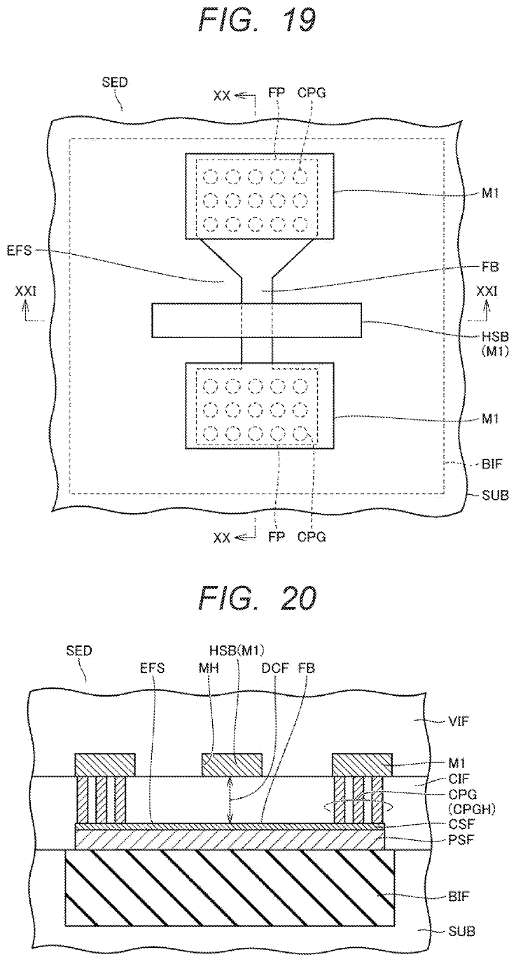

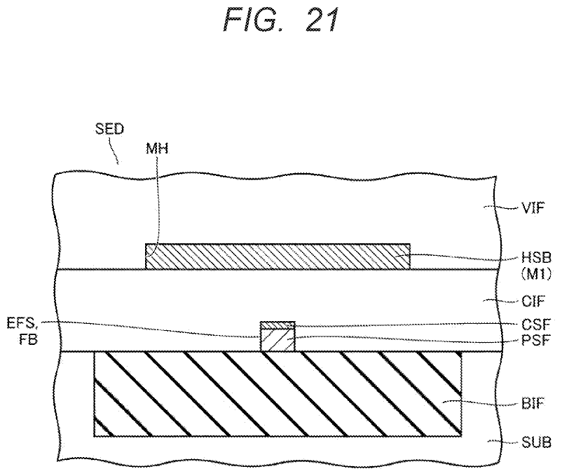

A third example of an electric fuse according to the third embodiment will be described. As shown in FIGS. 19, 20, and 21, the electric fuse EFS is disposed on the isolation dielectric film BIF formed in the semiconductor substrate SUB. The contact interlayer dielectric film CIF is formed to cover the electric fuse EFS. The contact plug CPG is formed in the contact hole CPGH penetrating the contact interlayer dielectric film CIF. The first wiring layer M1 is formed on the contact interlayer dielectric film CIF.

Further, the heat sink HSB that absorbs heat of the fuse body FB is formed on the contact interlayer dielectric film CIF as the first wiring layer M1. The heat sink HSB is formed from a position corresponding to the upper surface of the first wiring layer M1 to the upper surface of the contact interlayer dielectric film CIF facing the lower surface of the first wiring layer M1. The heat sink HSB is formed so as to extend in a direction intersecting with a direction in which the fuse body FB extends. The contact interlayer dielectric film CIF corresponding to the thickness DCF is interposed between the fuse body FB and the heat sink HSB. The via interlayer dielectric film VIF or the like is further formed so as to cover the first wiring layer M1 and the heat sink HSB. Note that substantially the same members as those of the electric fuse EFS shown in FIG. 2 and the like are denoted by the same reference numerals, and the explanation thereof will not be repeated unless otherwise required.

The above-described electric fuse EFS is formed in the same step as the step of forming the gate electrode of the driver transistor DTR (refer to FIG. 1), for example. After the electric fuse EFS is formed, the contact interlayer dielectric film CIF such as a silicon oxide film is formed so as to cover the electric fuse EFS. Here, the contact interlayer dielectric film CIF is formed to have a thickness that ensures the predetermined distance DCF between the heat sink HSB and the fuse body FB, which will be described later. The thickness DCF is, for example, about 0.05 μm to 2 μm.

Next, the contact hole CPGH is formed in the contact interlayer dielectric film CIF. The contact plug CPG is formed in the contact hole CPGH. Next, the first wiring layer M1 and the heat sink HSB are formed on the contact interlayer dielectric film CIF. Next, the via interlayer dielectric film VIF or the like is further formed so as to cover the first wiring layer M1 and the heat sink HSB.

In the above-described electric fuse EFS, the heat sink HSB is disposed directly above a portion to be melted in the fuse body FB. The heat sink HSB mainly has a function of absorbing heat generated by a current flowing through the cobalt silicide film CSF. Therefore, the heat of the portion to be melted in the fuse body FB is absorbed by the heat sink HSB, the temperature increasing rate of the cobalt silicide film CSF located in the portion to be melted becomes slower than when the heat sink HSB is not disposed with the passage of time from the start of the current flow, the time until the melting point is reached becomes longer.

Since the time until the temperature of the cobalt silicide film CSF reaches the melting point is longer than the time when the heat sink HSB is not disposed, the temperature of the polysilicon film PSF can be increased in the meantime. As a result, the temperature difference between the temperature (melting point) of the cobalt silicide film CSF and the temperature of the polysilicon film PSF is reduced, and the polysilicon film PSF is easily melted. Consequently, the electric fuse EFS can be cut more reliably.

In the third embodiment, it is explained that the heat sink HSB is formed so as to extend in a direction intersecting with the direction in which the fuse body FB extends. As the heat sink HSB, the heat sink HSB formed in a cylindrical shape may be disposed directly above the fuse body FB as in the case of the contact plug CPG.

Further, in each embodiment, the cobalt silicide film is exemplified as the metal silicide film of the electric fuse EFS, but the present disclosure can also be applied to, for example, a nickel silicide film, a tungsten silicide film, or a titanium silicide film. In addition, a polysilicon film is exemplified as the first layer and a metal silicide film is exemplified as the second layer, the material is not limited to the polysilicon film and the metal silicide film as long as the melting point of the second layer is higher than the melting point of the first layer and the electric fuse can be cut mainly by a current flowing through the second layer.

The electric fuse described in the respective embodiments can be variously combined as required.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a semiconductor substrate having a main surface; and
an electric fuse including a fuse body, the fuse body being formed on the main surface, having a width and extending in one direction,
wherein the fuse body includes:
a first layer having a first melting point;
a second layer laminated in contact with the first layer and having a second melting point higher than the first melting point;
a first portion to be cut as the electric fuse, the first portion having a first thickness; and
a second portion connected to the first portion and having a second thickness,
wherein the first thickness of the first portion is smaller than the second thickness of the second portion, and
wherein a thickness of the first layer in the first portion of the fuse body is smaller than a thickness of the first layer in the second portion.

2. A semiconductor device comprising:
a semiconductor substrate having a main surface; and
an electric fuse including a fuse body, the fuse body being formed on the main surface, having a width and extending in one direction,
wherein the fuse body includes:
a first layer having a first melting point;
a second layer laminated in contact with the first layer and having a second melting point higher than the first melting point;
a first portion to be cut as the electric fuse, the first portion having a first thickness; and
a second portion connected to the first portion and having a second thickness,
wherein the first thickness of the first portion is larger than the second thickness of the second portion, and
wherein a thickness of the second layer in the first portion of the fuse body is larger than a thickness of the second layer in the second portion.

3. The semiconductor device according to claim 1 or claim 2,
wherein the first layer is a polysilicon film, and
wherein the second layer is a metal silicide film.

4. The semiconductor device according to claim 3,
wherein the metal silicide film includes a cobalt silicide film.

5. A semiconductor device comprising:
a semiconductor substrate having a main surface;
an electric fuse including a fuse body, the fuse body being formed on the main surface, having a width and extending in a first direction; and
a heat sink disposed over the fuse body via a dielectric material,
wherein the fuse body includes:
a first layer having a first melting point; and
a second layer laminated in contact with the first layer between the first layer and the heat sink and having a second melting point higher than the first melting point.

6. The semiconductor device according to claim 5,
wherein the heat sink is formed to extend in a second direction intersecting with the first direction.

7. The semiconductor device according to claim 5, comprising:
a contact interlayer dielectric film formed to cover the main surface of the semiconductor substrate; and
a first wiring layer formed on the contact interlayer dielectric film,
wherein the heat sink is formed on the contact interlayer dielectric film, and
wherein a part of the contact interlayer dielectric film is interposed between the heat sink and the fuse body as the dielectric material.

8. The semiconductor device according to claim 7,
wherein the heat sink is formed from a position of an upper surface of the contact interlayer dielectric film corresponding to a lower surface of the first wiring layer to a position closer to the main surface of the semiconductor substrate than the lower surface of the first wiring layer.

9. The semiconductor device according to claim 7,
wherein the heat sink is formed from a position corresponding to an upper surface of the first wiring layer to an upper surface of the contact interlayer dielectric film corresponding to a lower surface of the first wiring layer.

10. The semiconductor device according to claim 5, comprising:
a contact interlayer dielectric film formed to cover the main surface of the semiconductor substrate;
a first wiring layer formed on the contact interlayer dielectric film;
a via interlayer dielectric film formed to cover the first wiring layer; and
a second wiring layer formed on the via interlayer dielectric film,
wherein the heat sink is formed from a position of an upper surface of the via interlayer dielectric film corresponding to a lower surface of the second wiring layer to a position closer to the main surface of the semiconductor substrate than an interface between the via interlayer dielectric film and the contact interlayer dielectric film, and
wherein a part of the contact interlayer dielectric film is interposed between the heat sink and the fuse body as the dielectric material.

11. The semiconductor device according to claim 5,
wherein the first layer is a polysilicon film, and
wherein the second layer is a metal silicide film.

12. The semiconductor device according to claim 11,
wherein the metal silicide film includes a cobalt silicide film.
